(19) United States
(12) Patent Application Publication
(10) Pub. No.: US 2014/0266220 A1
(43) Pub. Date: Sep. 18, 2014

(54) DETECTION OF ELECTROPLATING BATH CONTAMINATION

(71) Applicant: APPLIED MATERIALS, INC., Santa Clara, CA (US)

(72) Inventors: Chandru Thambidurai, Kalispell, MT (US); Robert O. Miller, Kalispell, MT (US)

(21) Appl. No.: 13/838,080

(22) Filed: Mar. 15, 2013

(51) Int. Cl. H01L 21/66

(52) U.S. Cl. CPC H01L 22/12
USPC 324/425

(57) ABSTRACT

A method for detecting contamination of a bath of electrolyte in an electroplating processor is performed by preparing a baseline plot using chronopotentiometry of a baseline sample of electrolyte having substantially the same chemical composition as the initial clean bath of the processor. A sample of the presently existing plating electrolyte from the processor is obtained. A processor sample plot is prepared using chronopotentiometry of the sample of plating electrolyte obtained from the processor. The baseline plot is compared to the processor sample plot. A substantial match between them indicates no contamination in the bath. Divergence between them indicates contamination in the bath. A library of contamination chronopotentiometric signatures may be used to test the bath.

### FIELD OF THE INVENTION

The field of the invention is methods and processors for electroplating semiconductor material wafers and similar types of substrates.

### BACKGROUND OF THE INVENTION

Microelectronic devices such as semiconductor devices are generally fabricated on and/or in substrates or wafers, in a typical fabrication process, one or more layers of metal or other conductive materials are formed on a wafer in an electroplating processor. The processor has a bath of electrolyte held in vessel or bowl with one or more anodes in the bowl. The wafer itself may be held in a rotor in a head movable into the bowl for processing and away from the bowl for loading and unloading. A contact ring on the rotor generally has a large number of contact fingers that make electrical contact with the wafer.

Due to their microscopic size and chemical and electrical characteristics, microelectronic devices are highly sensitive to particle and chemical contamination. Consequently, they are manufactured in clean rooms using highly cleaned equipment and very pure processing fluids. The bath of electrolyte in an electroplating processor must also remain free of contamination, to avoid defects in the microelectronic end products.

The electrolyte, may become contaminated from various sources, including traces of cleaning or other types of fluid remaining in or on the processor and its components from the original manufacturing of the processor. However, there are no existing advantageous techniques for detecting such contamination and there remains a need for them.

After a wafer is electroplated, the wafer may be inspected, for example via X-rays, to check for defects, if defects are detected, the cause of the defects must be determined and removed before production continues. Determining the cause the defects may foe a difficult challenge because many variables can affect plating quality and results. Techniques for helping to determine causes of plating defects are needed.

### BRIEF DESCRIPTION OF THE DRAWINGS

FIG. 1 is a graph of chronopotentiometry data of a control sample of electrolyte and of samples having different known concentrations of a first type of contamination.

### DETAILED DESCRIPTION

Chronopotentiometry is a known electrochemical analysis method for testing properties of liquids. In a method of the Invention, chronopotentiometry is modified and used to identify possible contamination. Bench top chronopotentiometry experiments may be conducted using a control bath and contaminating fluid. The contaminating fluid may be a fluid that is used in the manufacture of the processor. The contamination fluid may alternatively be another fluid suspected of causing contamination of the bath in the processor.

A test sample of a baseline or control bath is made up match the actual processor bath being tested in its uncontaminated or original condition. For testing the bath of a processor set up for electroplating copper onto a semiconductor wafer, the test sample contains the same organic compound additives as the actual processor bath. These are typically a suppressor (usually a high molecular weight polyalkene glycol such as PEG) and an accelerator (such as sodiumsulfopropyl or SPS). A leveler and optionally others may also be used, with or without the accelerator. These organic compounds are added to the processor bath to enhance plating performance.

The baseline sample is tested via chronopotentiometry in a bench top laboratory or test set up. Electrodes of a potentiostat are placed into the test sample, e.g. a 200 ml test sample in a beaker. A working electrode, a counter electrode and a reference electrode may be used, as is well known in potentiostat operation. A constant electrical current is passed through the baseline sample for a specified time, and voltage between the working electrode and the counter electrode is monitored. Plotting voltage over time provides the baseline plot shown in FIG. 1. The baseline plot shows the response that a processor bath should have if it is not contaminated.

In a basic form of the present method, the procedure above is then repeated using a sample of the bath from the processor. That is, a small amount of electrolyte is removed from the processor and tested via the potentiostat and a plot for the processor sample is generated. If this plot matches the baseline plot, no contamination is present in the processor bath. This means that defects on a wafer electroplated by the processor result from some other cause, and not from the bath.

Conversely, variations between the baseline plot and the plot of processor bath sample indicate contamination in the processor bath. The processor bath may then be replaced with fresh bath and manufacturing resumed.

The suspected contamination in the processor bath may be confirmed and identified with the following procedure. A small amount of a suspect contaminant, such as a manufacturing or cleaning fluid, is added to the baseline sample. Chronopotentiometry is performed again on the now contaminated baseline sample and the results plotted. The two tower plots in FIG. 1 are plots of contaminated baseline samples, a first sample contaminated at a concentration of 50 uL/L and a second sample contaminated at a concentration of 500 uL/L. These plots are then compared to the plot of the processor sample. A match between them indicates that the bath is contaminated with the manufacturing fluid (or whichever other contamination fluid was added to the baseline sample). Of course, the plots do not need to match exactly and a more general correlation may be used. As is apparent from FIG. 1, the absorbtion kinetics and level of suppression for the baseline is very different from the contaminated samples.

This test can also provide information on the concentration of contamination in the processor bath by determining which of the intentionally contaminated sample plots most closely matches the plot made for the processor bath sample. FIG. 1 shows two contaminated sample plots at 50 uL/L and 500 uL/L. Of course many more such contaminated sample plots may also be made and used to allow for greater accuracy in determining the concentration of contamination in the processor bath. Knowing the identity of the contaminant in the processor bath, and further knowing its concentration, may be helpful in removing the contamination from the processor bath and preventing future contamination of the processor bath.

Optionally, many different contaminants may be tested and plotted, to create a contaminant signature library. These may be archived and sorted into classes by their particular effects of uncontaminated control samples. The sorted archives may be used as look-up flies to simplify and streamline subsequent identification of contaminants in processor baths.

The chronopotentiometry testing as described above works because the suspected contaminants have organic components which either behave similarly to the organic additives in the processor bath, or interact with these organic additives to form complexes or compounds with the additives or their breakdown products. These chemical interactions consequently provide a chronopotentiometric signature which can be measured.

The method is simple, easy to perform and has high stability and repeatability. Also, the method is sensitive enough to detect possible contaminations in a new processor delivered to a customer site. The method can be expanded to determine breakdown products of organic additives and inorganic complexes in the processor bath.

The method described above may also be used during the manufacture of processors. Processor components, and components that touch the electrolyte, such as pumps, filters, tubes, heaters, fittings, valves, etc. may be tested by putting the component in contact with a simulated electrolyte bath. The simulated bath is then tested. If the component has con tarn incited the bath, a change in the chronopotentiometry data will occur. The component can then be more deeply cleaned or replaced. The processor is then less likely to have any bath contamination sources when fully manufactured and shipped to an end user.

Thus, novel methods have been shown and described. Various changes and substitutions may of course be made without departing from the spirit and scope of the invention. The invention, therefore, should not be limited except by the following claims and their equivalents.

1. A contamination detecting method for an electroplating processor provided with an initial clean bath of plating electrolyte including organic plating additives, comprising:
preparing a baseline plot using chronopotentiometry of a baseline sample of electrolyte having substantially the same chemical composition as the initial clean bath;
obtaining a sample of the plating electrolyte from the processor;
preparing a processor sample plot using chronopotentiometry of the sample of plating electrolyte obtained from the processor:
comparing the baseline plot to the processor sample plot; and
determining presence or absence of a contaminant in the bath of electrolyte in the processor based on the comparison of the samples.

2. The method of claim 1 further including determining the absence of contamination of the bath of plating electrolyte in the processor based on a substantial match between the baseline plot and the processor sample plot.

3. The method of claim 1 with the plating electrolyte comprising a copper plating electrolyte.

4. The method of claim 1 further comprising adding a known amount of a known contaminant to the baseline sample and preparing a contaminated baseline plot using chronopotentiometry and comparing the contaminated baseline plot to the processor sample plot to identify a contaminant in the bath of plating electrolyte in the processor.

5. The method of claim 4 further comprising adding a known amount of a plurality of contaminants to a plurality of baseline samples, and preparing a plurality of contaminated baseline plots using chronopotentiometry, and comparing the processor sample plot to the plurality of contaminated baseline plots to identify a contaminant in the bath of electrolyte in the processor.

6. The method of claim 5 further comprising storing the plurality of contaminated baseline plots to provide a library of contamination chronopotentiometric signatures.
